(19) United States
(12) Patent Application Publication
(10) Pub. No.: US 2008/0093655 A1
(43) Pub. Date: Apr. 24, 2008

(54) SEMICONDUCTOR DEVICE AND METHOD FOR FORMING THE SAME

(75) Inventors: Wook-Hyoung Lee, Seongnam-si (KR); Jeung-Hwan Park, Suwon-si (KR); Ki-Yeol Byun, Goyang-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/986,511

(22) Filed: Nov. 21, 2007

(30) Foreign Application Priority Data
Nov. 22, 2002 (KR) 10-2006-0116005

(51) Int. Cl. H01L 29/788; H01L 21/283

(52) U.S. Cl. 257/316; 438/593; 257/E29.3; 257/E21.159

(57) ABSTRACT

Provided are a semiconductor device and a method of forming the semiconductor device. The semiconductor substrate includes a cell region, a peripheral region, and a boundary region between the cell region and the peripheral region; a plurality of device isolation patterns defining the cell region, the peripheral region, and the boundary region; a plurality of floating gate patterns on the cell region; a gate pattern on the peripheral region; and a residual conductive pattern on the device isolation patterns defining the boundary region, wherein the residual conductive pattern is separated from an outermost one of the floating gate patterns by a distance from about 0.5 times to about 2 times a distance at which the floating gate patterns repeat.

### CROSS-REFERENCE TO RELATED APPLICATIONS

This U.S. non-provisional patent application claims priority under 35 U.S.C. § 119 of Korean Patent Application No. 10-2006-0116005, filed on Nov. 22, 2006, the entire contents of which are hereby incorporated by reference.

### BACKGROUND OF THE INVENTION

The present invention disclosed herein relates to a method of forming a semiconductor device, and more particularly, to a method of forming a non-volatile memory semiconductor device.

Non-volatile memory semiconductor devices include flash memory semiconductor devices. A flash memory semiconductor device includes cell transistors and peripheral transistors. A cell transistor includes a tunnel insulating layer, a floating gate electrode, a gate interlayer insulating layer, and a control gate electrode that are stacked together. A peripheral transistor includes a peripheral gate insulating layer and a peripheral gate electrode that are stacked together. Thus, a flash memory semiconductor device can have gate electrodes with different stacked structures in the cell region and the peripheral region.

Cell device isolation layers for defining an active region of a cell region on a semiconductor substrate, and peripheral device isolation layers for defining a peripheral active region of a peripheral region are formed on a semiconductor substrate. A boundary device isolation layer can be formed at the boundary region between the cell region and the peripheral region.

In order to form gate electrodes having respectively different stacked structures, various processes, including etching processes, for the cell region and the peripheral region can be alternately performed. When various processes are alternately performed, recesses can be formed in the upper portion of the boundary device isolation layer. Residue can be formed on the sidewalls between the recesses. Such residue is not easy to remove. Residue that is not removed can contaminate the cell region and the peripheral region. Accordingly, the properties of the semiconductor device are compromised.

To form the gate pattern of the cell region, an anti-reflection layer and a photoresist layer can be formed on a gate conductive layer. The anti-reflection layer and the photoresist layer can be unevenly formed on a conductive layer at the edge of the cell region due to recesses on the upper portion of the boundary device isolation layer. That is, the anti-reflection layer and the photoresist layer can have different thicknesses at the central portion of the cell region and at the edge thereof.

In an etching process for forming a gate pattern of the cell region, unevenness in thicknesses of the anti-reflection layer and the photoresist layer causes a loading effect to occur. The loading effect can cause irregular distribution of the critical dimension (CD) of the cell pattern. Thus, the distribution of a threshold voltage of the cell transistor can deteriorate.

### SUMMARY OF THE INVENTION

In accordance with aspects of the present invention there is provided a semiconductor device with improved properties of its cell transistor, and a method of forming the semiconductor device.

In accordance with one aspect of the present invention provided is a semiconductor device including: a semiconductor substrate including a cell region, a peripheral region, and a boundary region between the cell region and the peripheral region; a plurality of device isolation patterns defining the cell region, the peripheral region, and the boundary region; a plurality of floating gate patterns on the cell region; a gate pattern on the peripheral region; and a residual conductive pattern on the device isolation patterns defining the boundary region. The residual conductive pattern can be separated from an outermost one of the floating gate patterns by a distance from between about 0.5 times to about 2 times a distance at which the floating gate patterns repeat.

The device isolation patterns can have upper surfaces that are substantially flat and at substantially the same height.

The floating gate patterns and the residual conductive pattern can have upper surfaces that are at substantially the same height.

The gate pattern can include a first conductive pattern, and a second conductive pattern on the first conductive pattern, and the residual conductive pattern can be formed of the same material as that of the first conductive pattern.

The residual conductive pattern and the first conductive pattern can be each formed as a polysilicon layer.

The semiconductor device can further include a control gate pattern on the floating gate patterns. The control gate pattern can be formed of the same material as the second conductive pattern.

The control gate pattern and the second conductive pattern can each be formed as a silicon layer.

The semiconductor device can further include a third conductive pattern on the control gate pattern and the second conductive pattern. The third conductive pattern can include at least one of a tungsten layer and a tungsten silicon layer.

In accordance with another aspect of the present invention, provided is a method for forming a semiconductor device, include: preparing a semiconductor substrate including a cell region, a peripheral region, and a boundary region between the cell region and the peripheral region; forming device isolation patterns defining a cell active region and a peripheral active region and having a portion protruding higher than an upper surface of the semiconductor substrate, first conductive patterns on the cell active region and the peripheral active region, and a first insulating layer interposed between the cell active region and the first conductive layers and between the peripheral active region and the first conductive layers; forming a first buffer layer on the semiconductor substrate on which the first conductive layers are formed; removing the first buffer layer of the peripheral region, the first conductive layers, and the first insulating layer, and forming device isolation patterns of the boundary region and the peripheral region, the device isolation patterns having upper surfaces that are lower than the upper surfaces of the device isolation patterns of the cell region and simultaneously exposing the peripheral active region; forming a second insulating layer on the exposed peripheral active region; forming a second conductive layer and a second buffer layer on the semiconductor substrate having the second insulating layer formed thereon; removing the second buffer layer and the second conductive layer of the cell region, exposing a first buffer layer of the cell region, and forming a second conductive pattern that protrudes on the boundary region; and selectively etching the protruding second conductive pattern on the boundary region.

The selective etching of the protruding second conductive pattern can include simultaneously etching the exposed first buffer layer, the first buffer layer of the boundary region, and the second buffer layer of the boundary region and the peripheral region.

The second conductive pattern can have an etching selection ratio respectively to the first and second buffer layers.

The second conductive pattern can be a polysilicon layer, and the first and second buffer layers can be each formed of a medium temperature oxide layer.

The method can further include removing the first and second buffer layers and exposing the first conductive layers of the cell region and the second conductive pattern of the boundary and peripheral regions, after the selective etching of the protruding second conductive pattern.

The exposed second conductive pattern of the boundary region can be separated from an outermost one of the first conductive layers of the cell region by a distance from about 0.5 times to about 2 times a distance at which the first conductive layers repeat.

The method can further include recessing the device isolation pattern of the cell region and exposing upper surfaces and sidewalls of the first conductive layers, after the removing of the first and second buffer layers.

The method can further include: forming a third insulating layer on the semiconductor substrate to be conformal to the exposed upper surfaces and sidewalls of the first conductive layers; removing the third insulating layer of the peripheral region and exposing an upper surface of the second conductive pattern of the peripheral region; and forming a third conductive layer on the exposed upper surface of the second conductive pattern and the third insulating layer of the cell region.

The method can further include a fourth conductive layer on the third conductive layer.

The fourth conductive layer can include at least one of a tungsten layer and a tungsten silicide layer.

The method can further include: forming a third insulating layer on the semiconductor substrate to be conformal with the exposed upper surfaces and sidewalls of the first conductive layers; forming a third conductive layer on the third insulating layer; removing the third conductive layer and the third insulating layer of the peripheral region, and exposing the second conductive pattern of the peripheral region; and forming a fourth conductive layer on the exposed second conductive pattern of the peripheral region.

The fourth conductive layer can include at least one of a tungsten layer and a tungsten silicide layer.

### BRIEF DESCRIPTION OF THE FIGURES

The accompanying figures are included to provide a further understanding of the present invention, and are incorporated in and constitute a part of this specification. The drawings illustrate exemplary embodiments in accordance with aspects of the present invention and, together with the description, serve to explain principles thereof. In the figures:

FIG. 1 is a sectional view of an embodiment of a semiconductor device according to an aspect of the present invention;

FIGS. 2A through 2M are sectional views for describing an embodiment of a method of forming a semiconductor device according to the first aspect of the present invention; and

FIGS. 3A through 3N are sectional views for describing an embodiment of a method of forming a semiconductor device according to a second aspect of the present invention.

### DETAILED DESCRIPTION OF PREFERRED EMBODIMENTS

Preferred embodiments in accordance with aspects of the present invention will be described below in more detail with reference to the accompanying drawings. The present invention can, however, be embodied in different forms and should not be constructed as limited to the embodiments set forth herein.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

In the figures, the dimensions of layers and regions are exaggerated for clarity of illustration. It will also be understood that when a layer (or film) is referred to as being ‘on’ another layer or substrate, it can be directly on the other layer or substrate, or intervening layers can also be present. Further, it will be understood that when a layer is referred to as being ‘under’ another layer, it can be directly under, and one or more intervening layers can also be present. In addition, it will also be understood that when a layer is referred to as being ‘between’ two layers, it can be the only layer between the two layers, or one or more intervening layers can also be present. Like reference numerals refer to like elements throughout.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Hereinafter, exemplary embodiments in accordance with aspects of the present invention will be described with the accompanying drawings.

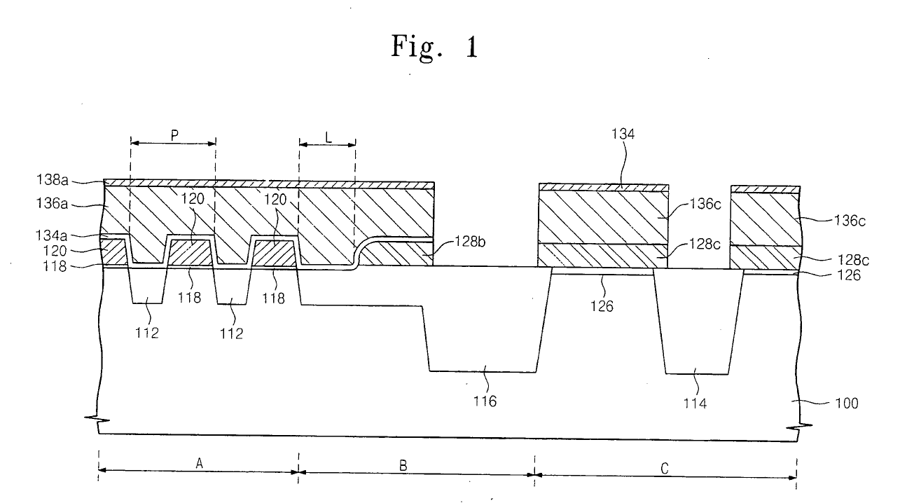

FIG. 1 is a sectional view of an embodiment of a semiconductor device according to an aspect of the present invention.

Referring to FIG. 1, a semiconductor substrate 100, having a cell region A, a peripheral region C, and a boundary region B between the cell region A and the peripheral region C, is provided. The semiconductor substrate 100 includes a cell active region of the cell region A, a peripheral active region of the peripheral region C, and the boundary region B are defined thereon, and device isolation patterns 112, 114, and 116 that are substantially flat with a common upper surface.

A plurality of floating gate patterns 120 protrude from the cell active regions. A cell gate insulating layer pattern 118 is disposed between the cell active regions and the floating gate patterns 120. A residual conductive pattern 128b is provided that has an upper surface that is substantially the same as the floating gate pattern 120 on the device isolation pattern 116 of the boundary region B. The distance at which the floating gate patterns 120 repeat can be defined as the pitch P. The residual conductive pattern 128b is distanced from the outermost floating gate pattern 120 of the cell region A by a distance L, measuring from 0.5×pitch P to 2×pitch P.

A gate interlayer insulating layer pattern 134a is formed in conformity on the floating gate patterns 120 and the residual conductive pattern 128b. A control gate pattern 136a is provided on the gate interlayer insulating layer pattern 134a. A fourth conductive pattern 138a is provided on the control gate pattern 136a. The fourth conductive pattern 138a can be a tungsten layer and/or a tungsten silicide layer, for example.

A gate pattern is provided on the peripheral active region. The gate pattern can include a first conductive pattern 128c and a second conductive pattern 136c on the first conductive pattern 128c. The first conductive pattern 128c can be formed of the same material as the residual conductive pattern 128b. For example, the residual conductive pattern 128b and the first conductive pattern 128c can be polysilicon layers. The second conductive pattern 136c can be formed of the same material as the control gate pattern 136a. For example, the second conductive pattern 136c and the control gate pattern 136a can be polysilicon layers. Alternatively, the second conductive pattern 136c can be formed of a different material than the control gate pattern 136a. For example, the second conductive pattern 136c can be a tungsten layer and/or a tungsten silicide layer, and the control gate pattern 136a can be a polysilicon layer. The fourth conductive pattern 138a is disposed on the second conductive pattern 136c. The fourth conductive pattern 138a can be a tungsten layer and/or a tungsten silicide layer.

A peripheral gate insulating layer pattern 126 can be interposed between the peripheral active region and the gate pattern. The peripheral gate insulating layer pattern 126 can include a high voltage gate insulating layer pattern and/or a low voltage gate pattern.

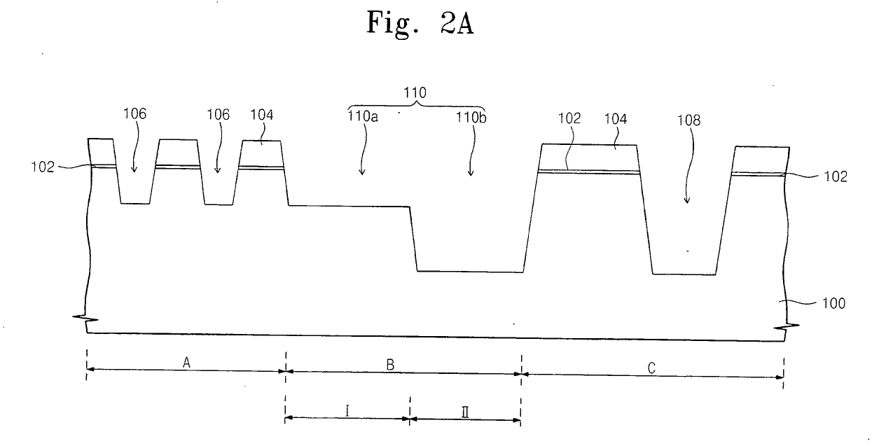

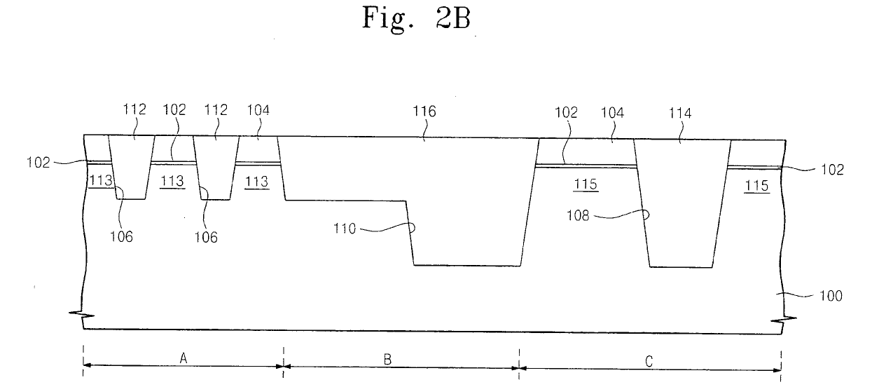

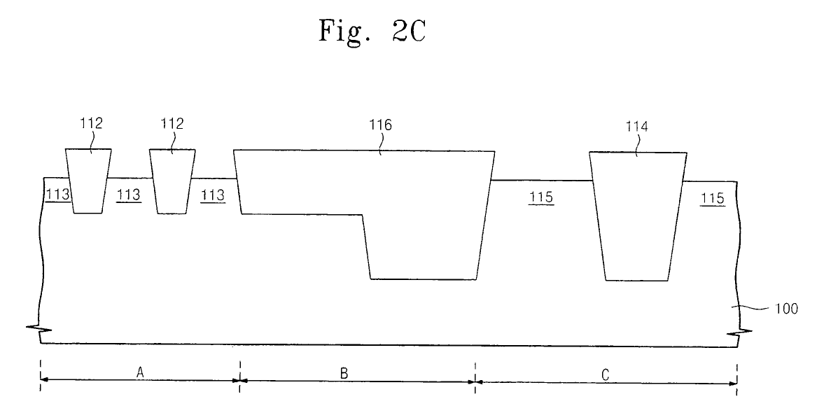

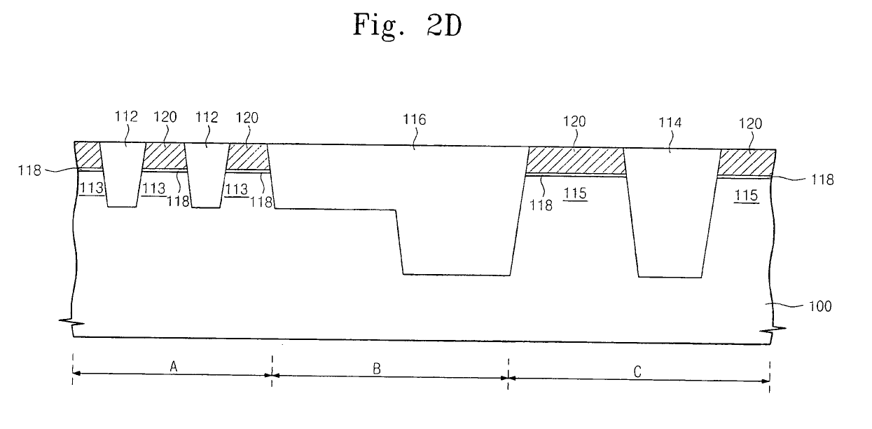

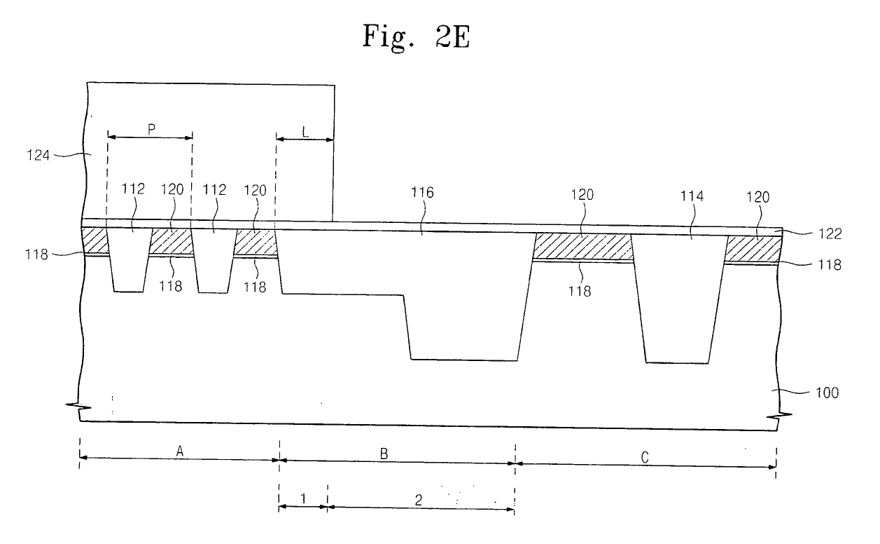

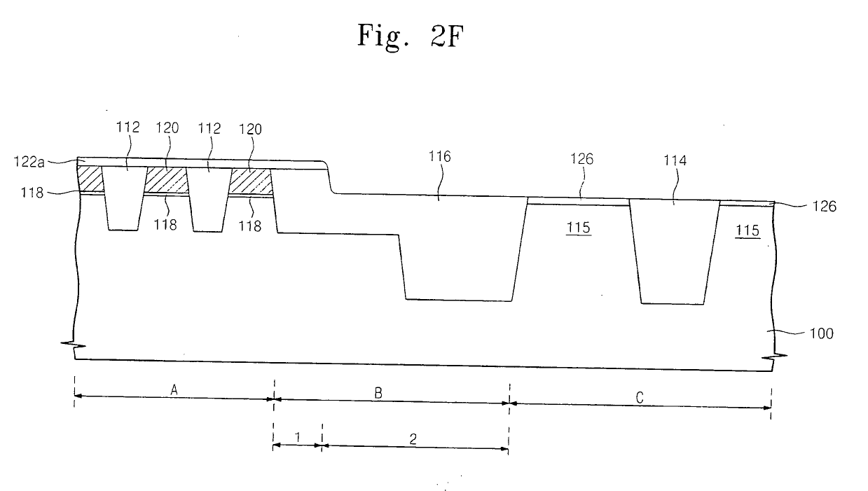

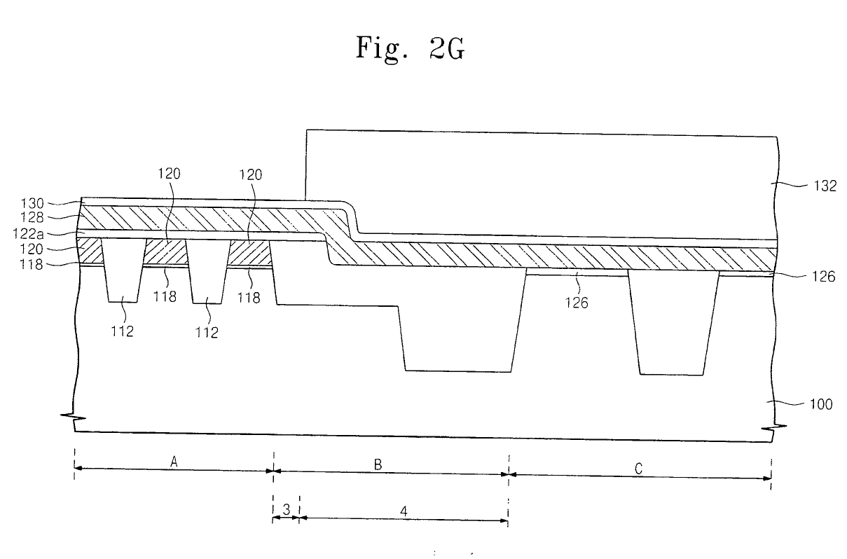

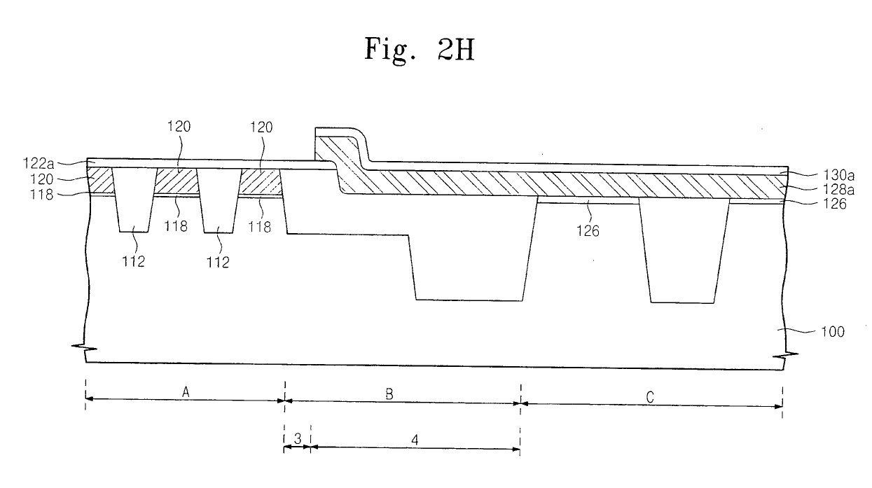

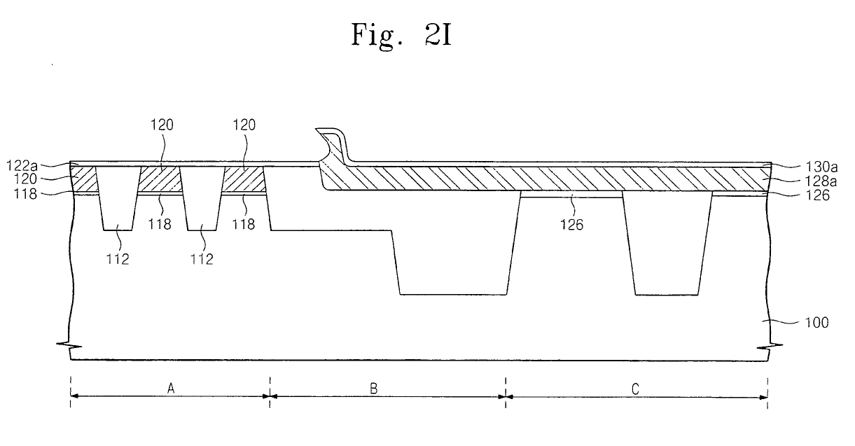

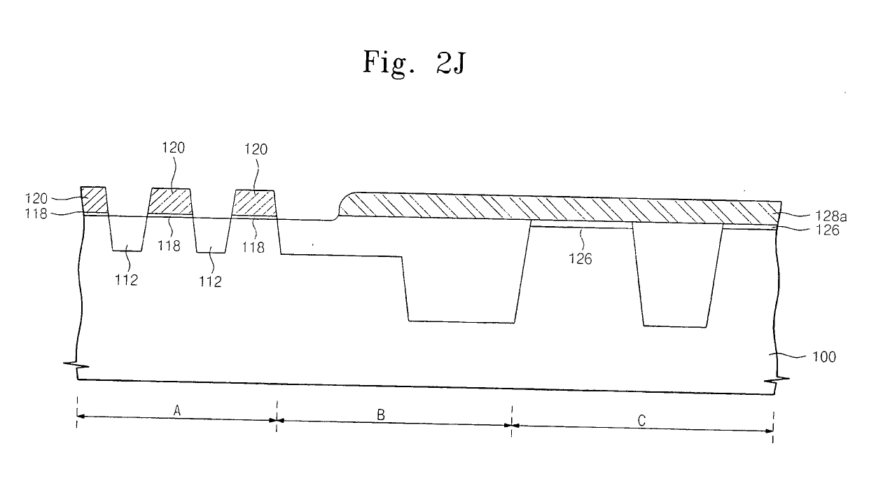

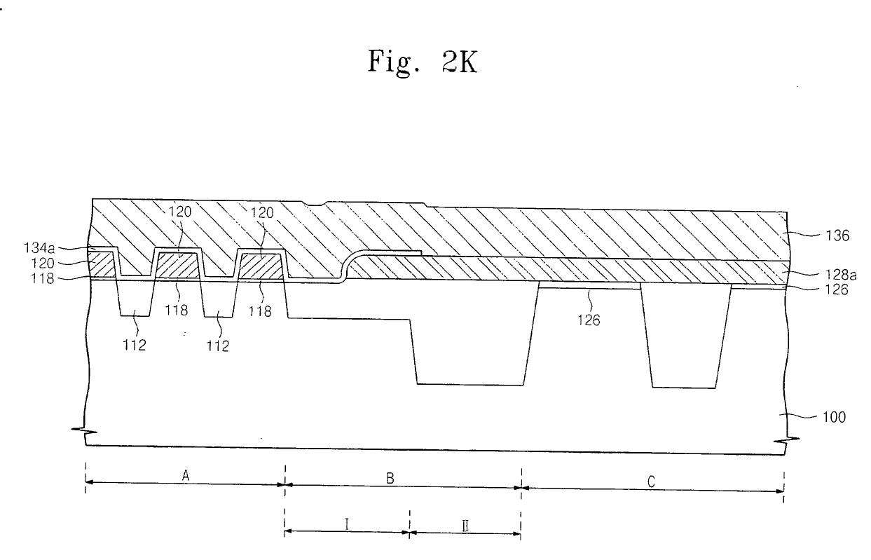

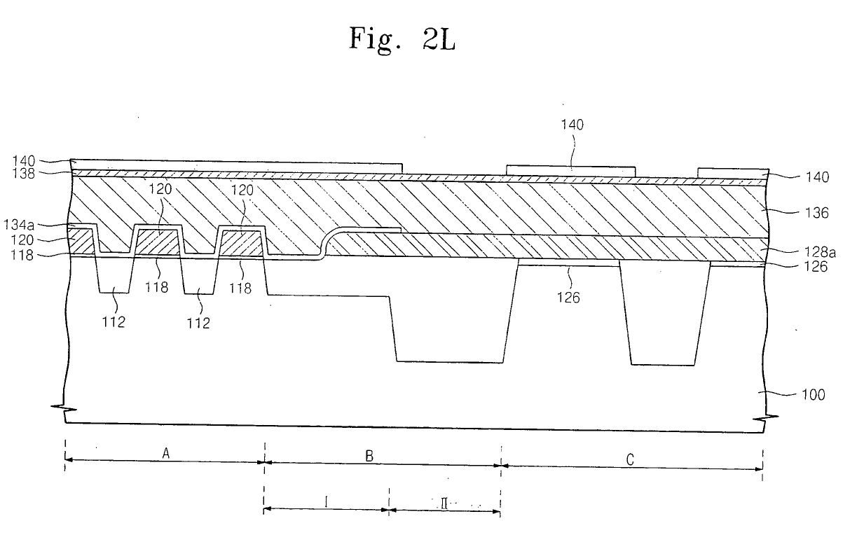

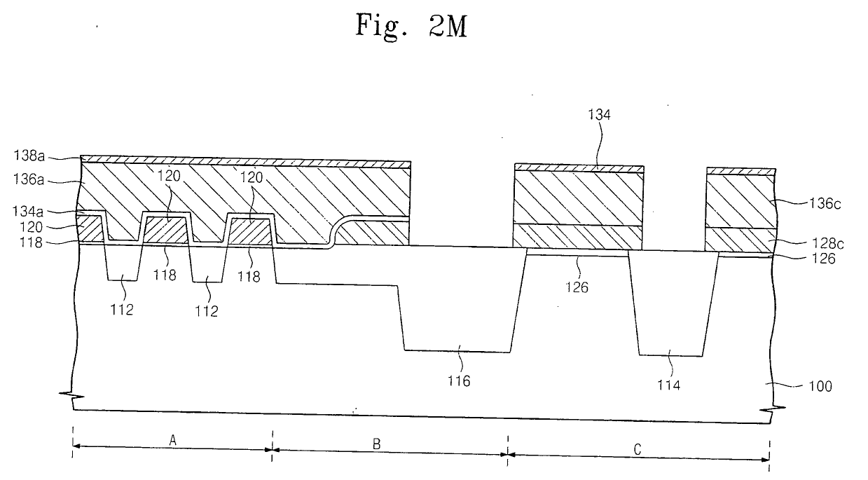

FIGS. 2A through 2M are sectional views for describing an embodiment of a method of forming a semiconductor device according to a first aspect of the present invention.

Referring to FIG. 2A, a semiconductor substrate 100 is provided which includes a cell region A, a peripheral region C, and a boundary region B between the cell region A and the peripheral region C. The boundary region B can include region I and region II.

Hard mask patterns 102 and 104 are formed on the semiconductor substrate 100. The hard mask patterns 102 and 104 can be a stacked pad-oxide layer 102 and a nitride layer 104. A first mask pattern (not shown) is formed to cover cell region A and region I. The first mask pattern can be a photoresist layer. The first mask pattern and the hard mask patterns 102 and 104 of the peripheral region C can be used as etching masks to etch the semiconductor substrate 100 and form trenches 108 and 110b in the peripheral region C and region II. The first mask pattern is then removed.

A second mask pattern (not shown) is formed to cover the peripheral region C and region II. The second mask pattern can be a photoresist layer. The second mask pattern and the hard mask patterns 102 and 104 of the cell region A can be used as etching masks to etch the semiconductor substrate 100 to form trenches 106 and 110a of the cell region A and region I. The second mask pattern is then removed. The trenches 106 and 110a in the cell region A and region I can be formed shallower than trenches 108 and 110b of the peripheral region C and region II. Thus, the trenches 106, 108, and 110 of the cell region A, the peripheral region C, and the boundary region B between the cell region A and the peripheral region C can be formed.

Referring to FIG. 2B, a first insulating layer is formed on the semiconductor substrate 100 having the trenches 106, 108, and 110 to fill the trenches 106, 108, and 110. The first insulating layer can be oxide layers formed through chemical vapor deposition (CVD). The first insulating layer filling the trenches 106, 108, and 110 is planarized to expose the hard mask patterns 102 and 104, and device isolation patterns 112, 116, and 114 defining a cell active region 113 and a peripheral active region 115 are formed. The planarizing can employ a chemical-mechanical polishing (CMP) process.

Referring to FIG. 2C, the hard mask patterns 102 and 104 are removed to expose the upper surface of the semiconductor substrate 100. Therefore, the device isolation patterns 112, 114, and 116 of the cell region A, the peripheral region C, and the boundary region B between the cell region A and the peripheral region C have portions that are higher than the upper surface of the exposed semiconductor substrate 100.

Referring to FIG. 2D, the second insulating layer 118 is formed on the cell active region 113 and the peripheral active region 115 of the semiconductor substrate 100 on which the device isolation patterns 112, 114, and 116 are formed. The second insulating layer 118 formed on the cell active region 113 can be a tunnel-insulating layer. Before a tunnel-insulating layer is formed, an ion implantation process can be performed to allow for a favorable threshold voltage of a subsequent cell transistor and improved punch through characteristics.

A first conductive layer is formed on the semiconductor substrate 100 on which the second insulating layer 118 is formed, and the spaces between the device isolation patterns 112, 114, and 116 are filled. The first conductive layer can be a polysilicon layer. To expose the device isolation patterns 112, 114, and 116, the first conductive layer is planarized, and a first conductive pattern 120 is formed on the second insulating layer 118. The first conductive pattern 120 on the cell region A can be a floating gate electrode. The planarizing can be performed using a chemical-mechanical polishing process.

Referring to FIG. 2E, a first buffer layer 122 is formed on the semiconductor substrate 100 having the first conductive patterns 120. The first buffer layer 122 can be a medium temperature oxide (MTO) layer. The mask pattern 124 can be formed on the first buffer layer 122 over the cell region A and on a portion of the first buffer layer 122 over the boundary region B. The portion of the boundary region B over which the mask pattern 124 is formed can be called the first region. The remaining region of the boundary region B on which the mask pattern 124 is not formed can be called the second region. The distance at which the first conductive patterns 120 repeat can be called the pitch P. The first region is distanced from the outermost floating first conductive pattern 120 of cell region A by a distance L, measuring from 0.5×pitch P to 2×pitch P.

Referring to FIG. 2F, the mask pattern 124 is used as an etching mask to etch the first buffer layer 122 on the second region and the first buffer layer 122, the device isolation pattern 114, and the first conductive pattern 120 of the device isolation pattern 116 and the peripheral region C until the second insulating layer 118 of the peripheral region C is exposed. Accordingly, the second insulating layer 118 of the mask pattern 124 and the peripheral region C is removed, and the upper surface of the first buffer pattern 122a and the peripheral active region 115 are exposed. Thus, the upper surfaces of the device isolation patterns 116 and 114 of the second region and the peripheral region C can be lower than the upper surfaces of the device isolation patterns 112 and 116 of the cell region A and the first region. The device isolation patterns 116 and 114 of the second region and the peripheral region C can share a common upper surface with the active region of the cell region A.

A third insulating layer 126 is formed on the peripheral active region 115. The third insulating layer 126 can be a peripheral gate insulating layer. The peripheral gate insulating layer can be a high voltage gate insulating layer and/or a low voltage gate insulating layer. In order for a subsequent peripheral transistor to have a favorable threshold voltage, an ion implantation process can be performed prior to forming the third insulating layer 126. During the performing of the ion implantation, the first conductive pattern 120 can be protected by the first buffer layer 122.

Referring to FIG. 2G, a second conductive layer 128 and a second buffer layer 130 are formed on the semiconductor substrate 100 on which the third insulating layer 126 is formed. The second buffer layer 130 can be an oxide layer. The second conductive layer 128 can be formed of a material that is etched more quickly than the first and second buffer layers 122 and 130. The etching selection ratios of the second conductive layer 128 with respect to the first and second buffer layers 122 and 130 can be in a range of about 5:1-10:1. For example, the second conductive layer 128 can be a polysilicon layer, and the first and second buffer layers 122 and 130 can be medium temperature oxide (MTO) layers. The second conductive layer 128 of the peripheral region C can be substantially the same thickness as the first conductive pattern 120.

The second buffer layer 130 of the peripheral region C and the second buffer layer 130 of the boundary region B have the mask pattern 132 formed thereon. The mask pattern 132 can be a photoresist layer. The remaining portion of the boundary region B on which the mask pattern 124 is not formed can be defined as a third region. The portion of the boundary region B on which the mask pattern 132 is formed can be defined as the fourth region.

Referring to FIG. 2H, the mask pattern 132 can be used as an etching mask to etch the cell region A, the second buffer layer 130 of the third region, and the second conductive layer 128 to form a second buffer pattern 130a of the fourth region and the peripheral region C and a second conductive pattern 128a. Accordingly, the first buffer pattern 122a of the cell region A and the third region is exposed. The mask pattern 132 is removed to expose upper surfaces of the fourth region and the second buffer pattern 130a of the peripheral region C. That is, a second conductive pattern 128a can be stepped and connected to protrude in the boundary region B.

Referring to FIG. 2I, the second conductive pattern 128a is selectively etched. The selective etching process allows the second conductive pattern 128a to be etched more quickly than the first and second buffer patterns 122a and 130a, respectively. The selective etching process can include the etching of the first buffer pattern 122a and the second buffer pattern 130a.

When the first and second buffer patterns 122a and 130a are almost completely removed, the protruding portion of the second conductive pattern 128a can be etched to a height corresponding approximately to the upper surface of the remainder of the second conductive pattern 128a.

Referring to FIG. 2J, the remaining first and second buffer patterns 122a and 130a are removed to expose the upper surfaces of the first conductive patterns 120 of the cell region A and the second conductive pattern 128a of the peripheral region C. The distance at which the first conductive patterns 120 repeat can be defined as the pitch P. The exposed second can be distanced from the outermost first conductive pattern 120 of cell region A by a distance L, measuring from 0.5×pitch P to 2×pitch P.

The device isolation patterns 112 of the cell region A can be recessed, and the upper surfaces and sidewalls of the first conductive patterns 120 can be exposed. The recessing process can be a wet etching process. Accordingly, the exposed area of the conductive patterns 120 is increased to increase a coupling ratio with a subsequent control gate electrode.

If the exposed second conductive pattern 128a is formed on a region too close to the outermost first conductive pattern 120 of the cell region A, the exposed second conductive pattern can form a short with the outermost first conductive pattern 120 of the cell region A. Alternatively, the exposed second conductive pattern 128a can be formed on a region too far from the outermost first conductive pattern 120 of the cell region A. When the device isolation patterns 112 of the cell region A and the exposed device isolation pattern 116 of the boundary region B are recessed, the device isolation pattern 116 of the boundary region B can be over-etched compared to the device isolation patterns 112 of the cell region A. When taking this into consideration, the exposed second conductive pattern 128a can be distanced from the outermost first conductive pattern 120 of cell region A by a distance L, measuring from 0.5×pitch P to 2×pitch P.

Referring to FIG. 2K, a fourth insulating layer is formed in conformity with the upper surface and sidewalls of the exposed first conductive patterns 120 on the semiconductor substrate 100. The fourth insulating layer of the cell region can be a gate interlayer insulating layer. The gate interlayer insulating layer can be a stack of a silicon oxide layer, a silicon nitride layer, and a silicon oxide layer.

The peripheral region C and the fourth insulating layer of region II are removed to form a fourth insulating pattern 134a, and the upper surface of the second conductive pattern 128a of the peripheral region C is exposed. A third conductive layer 136 is formed on the exposed upper surface of the second conductive pattern 128a and the fourth insulating pattern 134a. The third conductive layer 136 of the peripheral region C can have a thickness substantially similar to the distance from the upper surface of the first conductive patterns 120 to the upper surface of the third conductive layer 136.

Referring to FIG. 2L, a fourth conductive layer 138 having a low resistance can be formed on the third conductive layer 136. For example, the fourth conductive layer 138 can be a tungsten silicide layer or a tungsten layer. A hard mask layer can be formed on the fourth conductive layer 138. An anti-reflection layer (not shown) and a photoresist layer (not shown) can be formed on the hard mask layer. For example, a nitride layer can be used as the hard mask layer, and a non-photosensitive organic layer can be used as the anti-reflection layer. The organic layer (not shown) and the photoresist layer (not shown) can be formed through a spin coating process. The photoresist layer becomes a photoresist pattern through an exposing process. The photoresist pattern is used as an etching mask to etch the anti-reflection layer and the hard mask layer, to form an anti-reflection layer pattern (not shown) and a hard mask pattern 140. The photoresist pattern and the anti-reflection layer pattern are removed and the hard mask pattern 140 is exposed.

Referring to FIG. 2M, the hard mask pattern 140 is used as an etching mask to etch the fourth conductive layer 138, the third conductive layer 136, and the second conductive layer 128, in order to form cell gate pattern 136a, second conductive pattern 136a, and fourth conductive pattern 136c.

According to aspects of the present invention, recesses are not created on the upper portion of the device isolation pattern on the boundary region B between the cell region A and the peripheral region C. Moreover, the protruding portion of the second conductive layer pattern 128a in the boundary region B is selectively etched, so that the upper surface of the second conductive pattern 128a is planarized overall on the boundary region B and the peripheral region. By forming a third conductive layer 136 on the semiconductor substrate 100 having the planarized second conductive pattern 128a, the upper surface of the third conductive layer 136 of the cell region A can retain a planarized state. Therefore, when forming the anti-reflection layer and the photoresist layer on the third conductive layer 136 including the fourth conductive layer 138 for planarizing the gate pattern, a uniform thickness of the anti-reflection layer and the photoresist layer can be formed. The difference in thicknesses between the anti-reflection layer and the photoresist layer at the central portion and edge of the cell region A substantially reduces occurrence of the loading effect, and the distribution of critical dimensions of the cell gate pattern can be uniform. Thus, the threshold voltage distribution of the cell transistor can be improved.

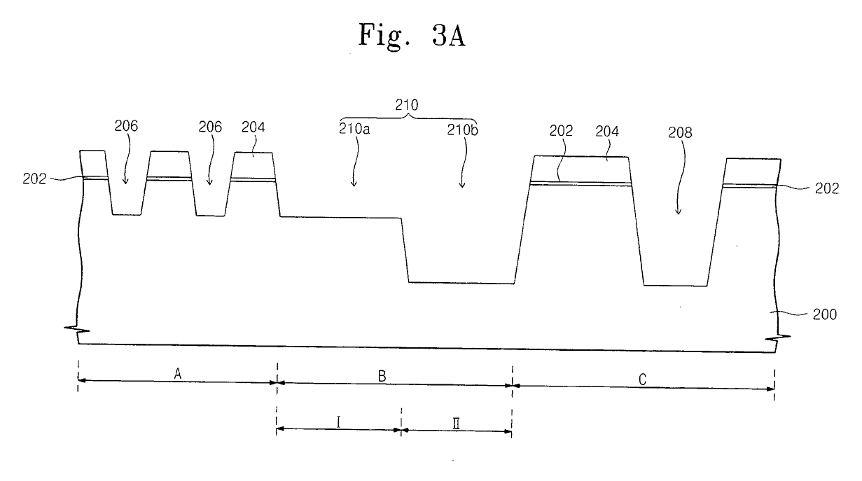

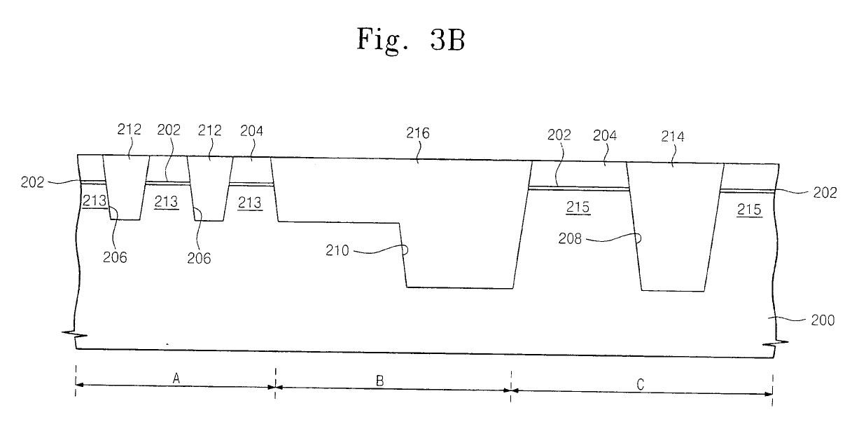

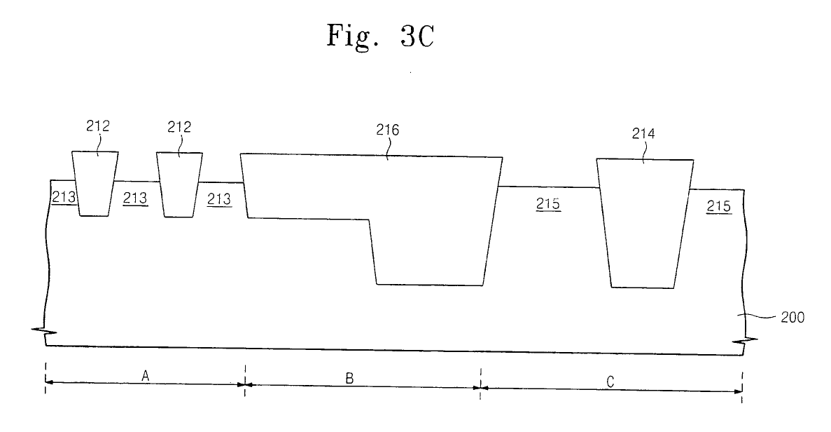

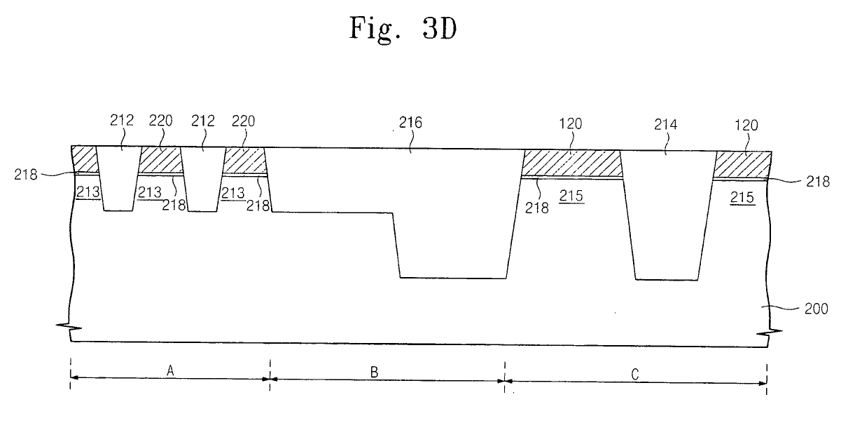

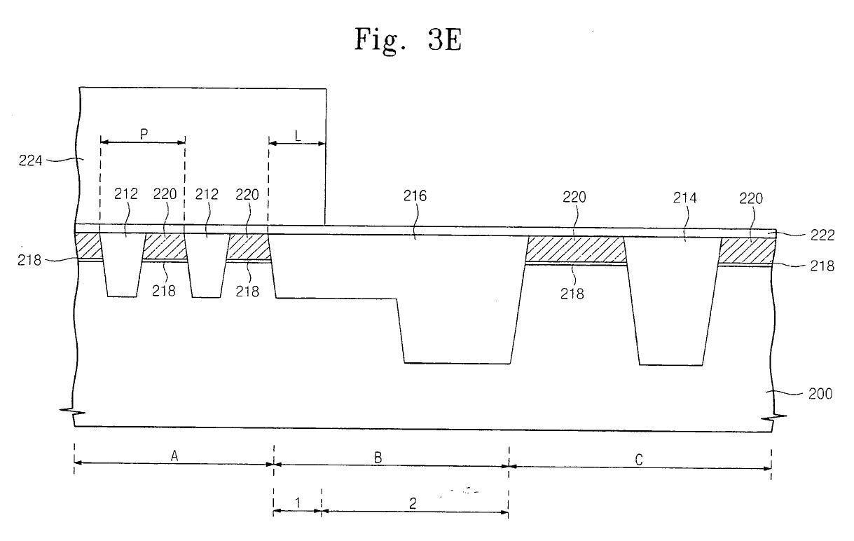

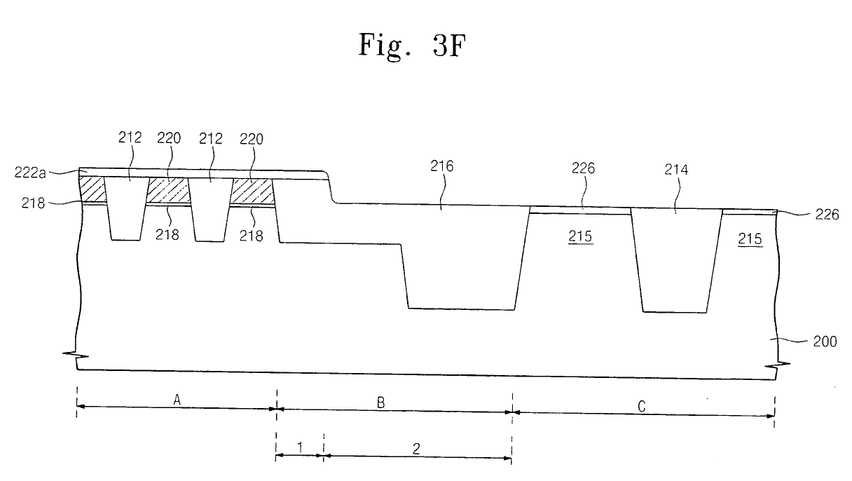

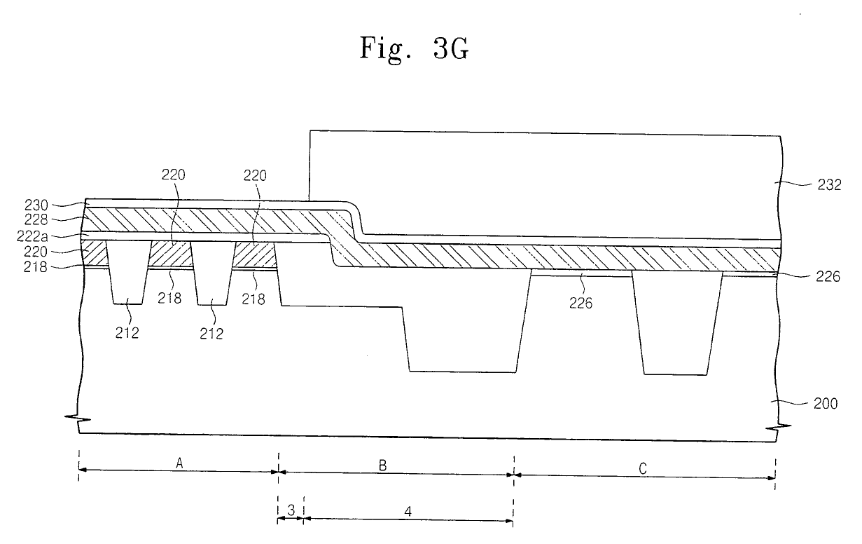

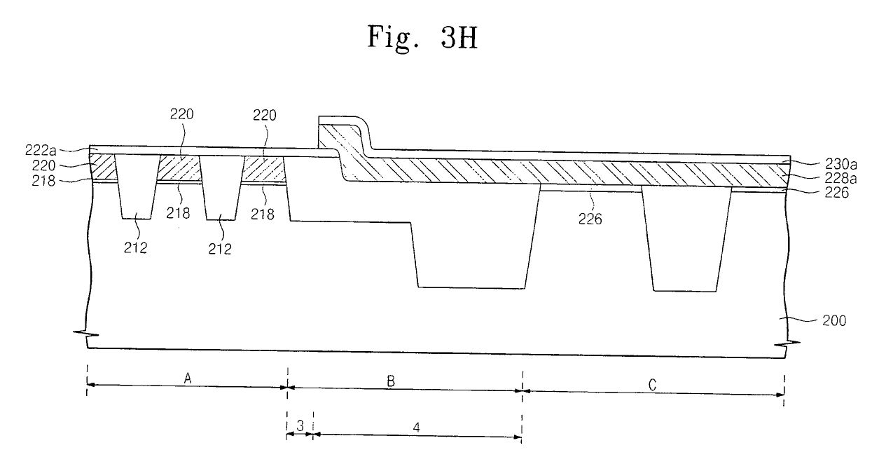

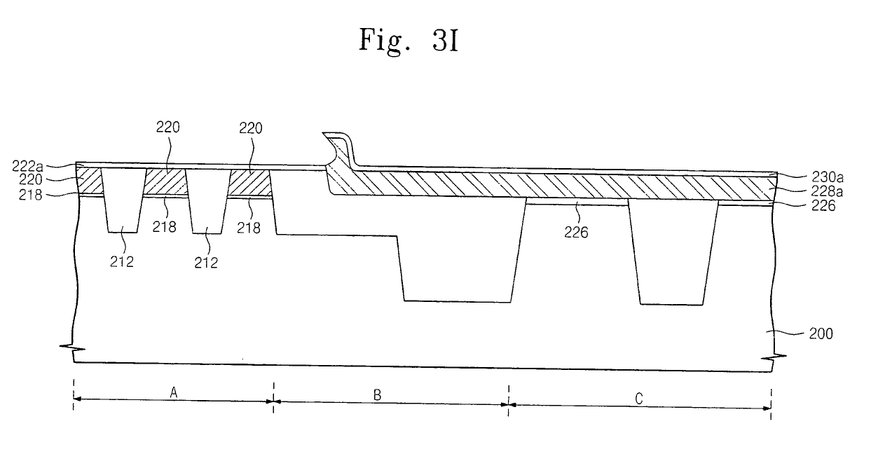

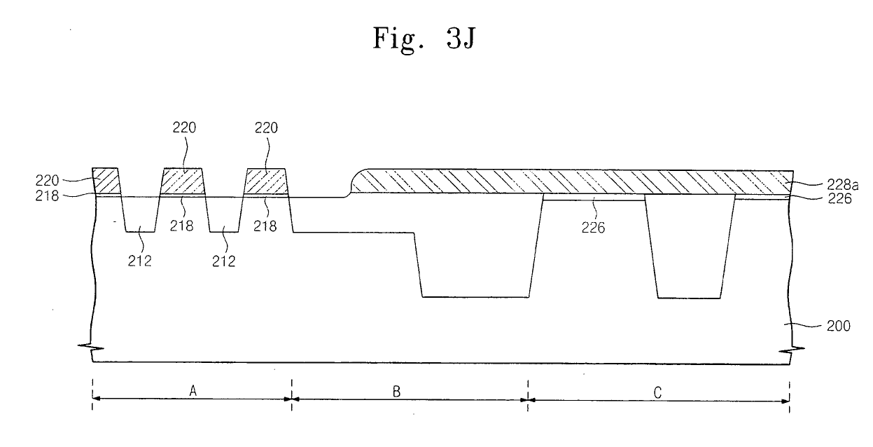

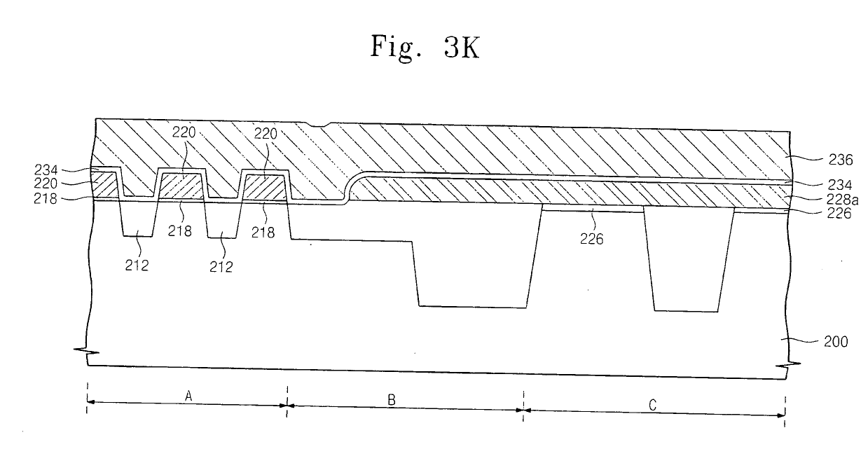

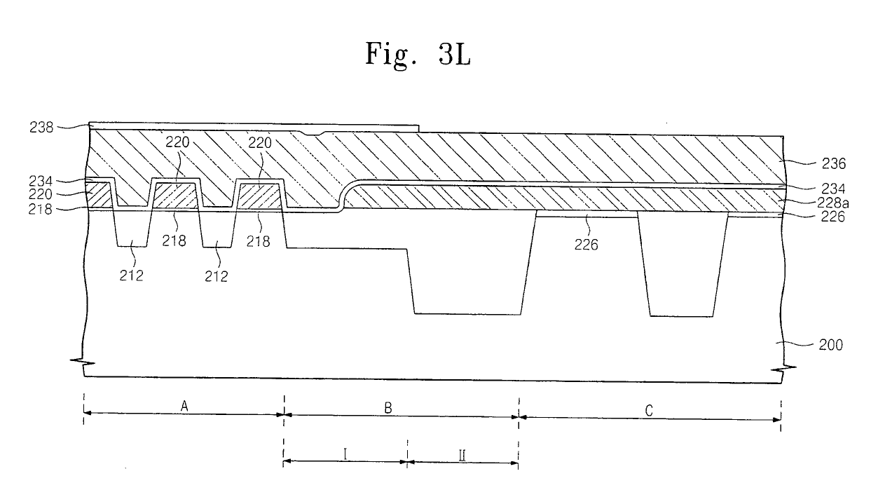

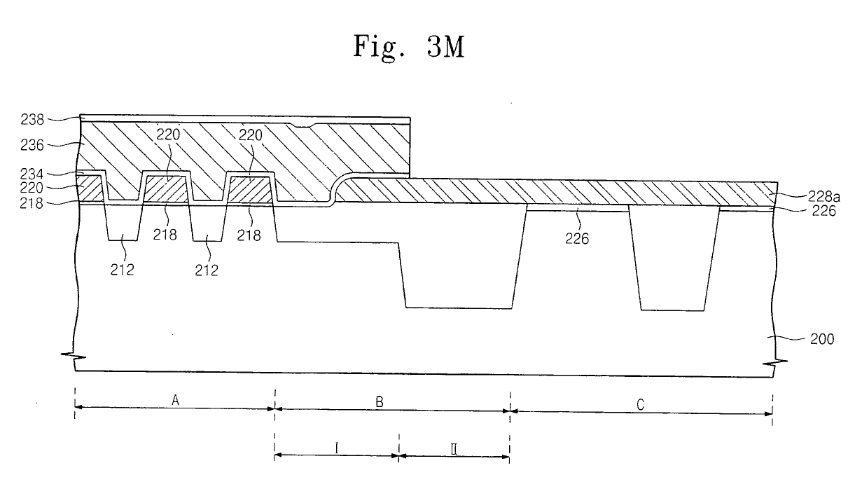

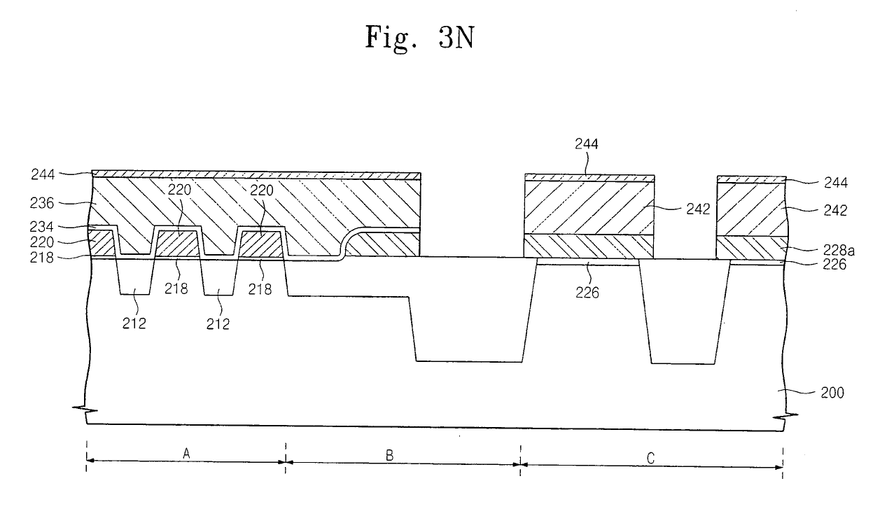

FIGS. 3A through 3N are sectional views for describing an embodiment of a method of forming a semiconductor device according to the second aspect of the present invention.

Referring to FIG. 3A, a semiconductor substrate 200, including a cell region A, a peripheral region C, and a boundary region B between the cell region A and the peripheral region C, is provided. The boundary region B includes a region I and a region II.

Hard mask patterns 202 and 204 are formed on the semiconductor substrate 200. The hard mask patterns 202 and 204 can be stacks of a pad-oxide layer 202 and a nitride layer 204. A first mask pattern (not shown) is formed on and covers the cell region A and the region I. The first mask pattern can be a photoresist layer. The hard mask patterns 202 and 204 of the first mask pattern and the peripheral region C are used as etching masks to etch the semiconductor substrate 200 and form trenches 208 and 210b of the peripheral region C and region II. The first mask pattern is then removed.

A second mask pattern (not shown) for covering the peripheral region C and region II is formed. The second mask pattern can be a photoresist layer. The hard mask patterns 202 and 204 of the second mask pattern and the cell region A are used as etching masks to etch the semiconductor substrate 200 and form trenches 206 and 210a of the cell region A and region I. The second mask pattern is then removed. The trenches 206 and 210a of the cell region A and region I are formed shallower than trenches 208 and 210b of the peripheral region C and region II. Thus, trenches 206, 208, and 210 can be formed for the cell region A, the peripheral region C, and the boundary region B between the cell region A and the peripheral region C.

Referring to FIG. 3B, a first insulating layer is formed on the semiconductor substrate 200 filling the trenches 206, 208, and 210. The first insulating layer can be an oxide layer formed using a chemical vapor deposition (CVD) process. The first insulating layer filling the trenches 206, 208, and 210 is planarized to expose the hard mask patterns 202 and 204, and device isolation patterns 112, 116, and 214 are formed to define a cell active region 213 and a peripheral active region 215. The planarizing process used can be a chemical-mechanical polishing process.

Referring to FIG. 3C, the hard mask patterns 202 and 204 are removed to expose the upper surface of the semiconductor substrate 200. Accordingly, the device isolation patterns 212, 214, and 216 of the cell region, the peripheral region C, and the boundary region B between the cell region A and the peripheral region C have portions protruding higher than the exposed upper surface of the semiconductor substrate 200.

Referring to FIG. 3D, a second insulating layer 218 is formed on the cell active region 213 and the peripheral active region 215 of the semiconductor substrate with the device isolation patterns 212, 214, and 216 formed thereon. The second insulating layer 218 formed on the cell active region 213 can be a tunnel-insulating layer. Before the tunnel-insulating layer is formed, an ion implantation process can be performed to give a subsequent cell transistor a favorable threshold voltage and improved punch through characteristics.

A first conductive layer is formed on the semiconductor substrate 200 with the second insulating layer 218 formed thereon, filling the spaces between the device isolation patterns 212, 214, and 216. The first conductive layer can be a poly silicon layer. To expose the device isolation patterns 212, 214, and 216, the first conductive layer is planarized, and a first conductive pattern 220 is formed on the second insulating layer 218. The first conductive pattern 220 on the cell region A can be a floating gate electrode. The planarizing process can be performed using chemical-mechanical polishing.

Referring to FIG. 3E, a first buffer layer 222 is formed on the semiconductor substrate 200 having the first conductive patterns 220. The first buffer layer 222 can be a medium temperature oxide layer. A mask pattern 224 can be formed in the first buffer layer of the cell region A and the first buffer layer 222 of the boundary region B. A predetermined region in the boundary region B in which the mask pattern 224 is formed can be defined as a first region. The remaining region of the boundary region B in which the mask pattern 224 is not formed can be defined as a second region. The distance at which the first conductive patterns 220 repeat can be defined as the pitch P. The first region can be distanced from the outermost floating first conductive pattern 220 of the cell region A by a distance L, measuring from 0.5×pitch P to 2×pitch P.

Referring to FIG. 3F, the mask pattern 224 is used as an etching mask to etch the first buffer layer 222 and the device isolation pattern 216 of the second region, and the first buffer layer 222, the device isolation pattern 214, and the first conductive patterns 220 of the peripheral region C, until the second insulating layer 218 of the peripheral region C is exposed. Then, the mask pattern 224 and the second insulating layer 218 of the peripheral region C are removed, and the upper surface of the first buffer pattern 222a and the peripheral active region 215 are exposed. Thus, the device isolation patterns 216 and 214 of the second region and the peripheral region C are given upper surfaces that are lower than upper surfaces of the device isolation patterns 212 and 216 of the cell region A and the first region. The device isolation patterns 216 and 214 of the second region and the peripheral region C can have a substantially same upper surface of the active region of the cell region A.

A third insulating layer 226 is formed on the peripheral active region 215. The third insulating layer 226 can be a peripheral gate insulating layer. The peripheral gate insulating layer can include a high voltage gate insulating layer and/or a low voltage gate insulating layer. In order to give the subsequent peripheral transistor a favorable threshold voltage, ion implantation can be performed before the third insulating layer 226 is formed. During the performing of the ion implantation, the first conductive pattern 220 can be protected by the first buffer layer 222.

Referring to FIG. 3G, a second conductive layer 228 and a second buffer layer 230 are formed on the semiconductor substrate 200 having the third insulating layer 226 formed thereon. The second conductive layer 228 can be formed of a material that is etched more quickly than the first and second buffer layers 222 and 230. The etching selection ratios of the 5 second conductive layer 228 with respect to the first and second buffer layers 222 and 230 of can be in a range of about 5:1-10:1. For example, the second conductive layer 228 can be a silicon layer, and the first and second buffer layers 222 and 230 can be oxide layers. The second conductive insulating layer 228 of the peripheral region C can have substantially the same thickness as the first conductive pattern 220.

A mask pattern 232 is formed on the second buffer layer 230 of the peripheral region C and the second buffer layer 230 of the boundary region B. The mask pattern 232 can be a photoresist layer. A predetermined region in the boundary region B having the mask pattern 232 formed thereon can be defined as a fourth region. The remaining portion of the boundary region B on which the mask pattern 232 is not formed can be defined as the third region.

Referring to FIG. 3H, the mask pattern 232 is used as an etching mask to etch the second buffer layer 230 of the cell region A and the third region, and the second conductive layer 228, to a form second buffer pattern 230a on the fourth region and the peripheral region C and a second conductive pattern 228a. Accordingly, the second conductive pattern 222a on the cell region A and the third region is exposed. The mask pattern 232 is removed, and the upper surfaces of the fourth region and the second buffer pattern 230a of the peripheral region C are exposed. That is, the second conductive pattern 228a can be formed to protrude on the boundary region B in accordance with the stepped shape of the boundary region B.

Referring to FIG. 3I, the protruding second conductive pattern 228a is selectively etched. The selective etching can etch the second conductive pattern 228a at a higher etching speed than the first and second buffer patterns 222a and 230a, respectively. The selective etching can include etching the first buffer pattern 222a and the second buffer pattern 230a.

When the first and second buffer patterns 222a and 230a are almost completely removed, the protruding portion of the second conductive pattern 228a can be etched to a level corresponding to an upper surface of the second conductive pattern 228a on the peripheral region C.

Referring to FIG. 3J, the remaining first and second buffer patterns 222a and 230a are removed, and upper surfaces of the first conductive pattern of the cell region A and the second conductive pattern of the peripheral region C are exposed. The exposed second conductive pattern 228a can be formed at a length L between 0.5×pitch P and 2×pitch P from the outermost first conductive pattern 220 of the cell region A.

The device separation patterns 212 of the cell region A are recessed to expose the upper surfaces and the side walls of the first conductive pattern 220. The recessing process can be a wet etching process. Accordingly, the exposed surface of the conductive pattern 220 is increased, thus increasing the coupling ratio with a subsequent gate electrode.

If the exposed second conductive pattern 228a is formed too proximate to the outermost first conductive pattern 220 of the cell region A, the exposed second conductive pattern 228a and the outermost first conductive pattern 220 on the cell region A can short. Conversely, the exposed second conductive pattern 228a can be formed too far from the outermost first conductive pattern 220 of the cell region A. When the device isolation patterns 212 of the cell region A and the exposed device isolation pattern 116 of the boundary region B are recessed, compared to the device isolation patterns 212 of the cell region A, the exposed device isolation pattern 216 of the boundary region B can be over-etched. Keeping this in mind, the exposed second conductive pattern 228a can be formed at a length L of between 0.5×pitch P and 2×pitch P from the outermost first conductive pattern 220 of the cell region A.

Referring to FIG. 3K, a fourth insulating layer 234 is formed in conformity with the upper surface and the sidewalls of the exposed first conductive patterns 220 on the semiconductor substrate 200. The fourth insulating layer 234 of the cell region A can be a gate interlayer insulating layer. The gate interlayer insulating layer can be a silicon oxide layer, a silicon nitride layer, and a silicon oxide layer. A third conductive layer 236 can be formed on the fourth insulating layer 234. The third conductive layer 236 on the peripheral region C can have a thickness that is substantially the same as the thickness from the upper surface of the first conductive patterns 220 to the upper surface of the third conductive layer 236.

Referring to FIGS. 3L and 3M, a first hard mask pattern 238 can be formed on the upper surface of the third conductive layer 236 on the cell region A and region I. The first hard mask pattern 238 is used as an etching mask to etch third conductive layer 236 on region II and the fourth insulating layer 234, to expose the second conductive layer 228 of the peripheral region C.

Referring to FIG. 3N, a fourth conductive layer 242 can be formed on the second conductive pattern 228a of the peripheral region C. The fourth conductive pattern 242 can be a polysilicon layer. A fifth conductive layer 244 having a low resistance can be formed on the third conductive layer 236 and the fourth conductive layer 242. For example, the fifth conductive layer can be a tungsten silicide layer or a tungsten layer. A second hard mask pattern 240 is formed on the fifth conductive layer 244. The second hard mask pattern 240 is used as an etching mask to etch the fifth conductive layer 244, the third conductive layer 236, and the second conductive layer 228, and form a cell gate pattern and a peripheral gate pattern.

As described above, recesses do not occur on the upper surface of a device isolation pattern at a boundary region between a cell region and a peripheral region, according to aspects of the present invention. Moreover, when patterning the cell gate pattern, the levelness of the conductive layer upper surface of the cell region can be maintained. Thus, when forming an anti-reflection layer and a photoresist layer on a conductive layer of the cell region for patterning the cell gate pattern, the anti-reflection layer and the photoresist layer can be formed in a uniform thickness. Therefore the occurrence of the loading effect due to a difference in thickness of the cell region at the central portion and the edge thereof can be substantially reduced, and the critical dimension distribution of the cell gate pattern can be uniform. Resultantly, the threshold voltage distribution of a cell gate transistor is improved.

The above-disclosed subject matter is to be considered illustrative, and not restrictive, wherein the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor device comprising:
a semiconductor substrate including a cell region, a peripheral region, and a boundary region between the cell region and the peripheral region;
a plurality of device isolation patterns defining the cell region, the peripheral region, and the boundary region;
a plurality of floating gate patterns on the cell region;
a gate pattern on the peripheral region; and
a residual conductive pattern on the device isolation patterns defining the boundary region, wherein the residual conductive pattern is separated from an one outermost of the floating gate patterns by a distance from about 0.5 times to about 2 times a distance at which the floating gate patterns repeat.

2. The semiconductor device of claim 1, wherein the device isolation patterns have upper surfaces that are substantially flat and at substantially the same height.

3. The semiconductor device of claim 1, wherein the floating gate patterns and the residual conductive pattern have upper surfaces that are at substantially the same height.

4. The semiconductor device of claim 1, wherein the gate pattern comprises a first conductive pattern, and a second conductive pattern on the first conductive pattern, and
the residual conductive pattern is formed of the same material as that of the first conductive pattern.

5. The semiconductor device of claim 4, wherein the residual conductive pattern and the first conductive pattern are each formed as a polysilicon layer.

6. The semiconductor device of claim 4, further comprising a control gate pattern on the floating gate patterns, wherein the control gate pattern is formed of the same material as the second conductive pattern.

7. The semiconductor device of claim 6, wherein the control gate pattern and the second conductive pattern are each formed as a silicon layer.

8. The semiconductor device of claim 6, further comprising a third conductive pattern on the control gate pattern and the second conductive pattern, the third conductive pattern comprising at least one of a tungsten layer and a tungsten silicon layer.

9. A method for forming a semiconductor device, comprising:
preparing a semiconductor substrate including a cell region, a peripheral region, and a boundary region between the cell region and the peripheral region;
forming device isolation patterns defining a cell active region and a peripheral active region, the device isolation patterns having a portion protruding higher than an upper surface of the semiconductor substrate,
first conductive layers on the cell active region and the peripheral active region, and a first insulating layer interposed between the cell active region and the first conductive layers and between the peripheral active region and the first conductive layers;
forming a first buffer layer on the semiconductor substrate on which the first conductive layers are formed;
removing the first buffer layer of the peripheral region, the first conductive layers, and the first insulating layer, and forming device isolation patterns of the boundary region and the peripheral region, the device isolation patterns having upper surfaces that are lower than the upper surfaces of the device isolation patterns of the cell region and simultaneously exposing the peripheral active region;
forming a second insulating layer on the exposed peripheral active region;
forming a second conductive layer and a second buffer layer on the semiconductor substrate having the second insulating layer formed thereon;
removing the second buffer layer and the second conductive layer of the cell region, exposing a first buffer layer of the cell region, and forming a second conductive pattern that protrudes on the boundary region; and
selectively etching the protruding second conductive pattern on the boundary region.

10. The method of claim 9, wherein the selective etching of the protruding second conductive pattern comprises simultaneously etching the exposed first buffer layer, the first buffer layer of the boundary region, and the second buffer layer of the boundary region and the peripheral region.

11. The method of claim 10, wherein the second conductive pattern has an etching selection ratio relative to the first and second buffer layers.

12. The method of claim 11, wherein the second conductive pattern is a polysilicon layer, and the first and second buffer layers are each formed of a medium temperature oxide layer.

13. The method of claim 9, further comprising removing the first and second buffer layers and exposing the first conductive layers of the cell region and the second conductive pattern of the boundary and peripheral regions, after the selective etching of the protruding second conductive pattern.

14. The method of claim 13, wherein the exposed second conductive pattern of the boundary region is separated from an outermost one of the first conductive layers of the cell region by a distance from about 0.5 times to about 2 times a distance at which the first conductive layers repeat.

15. The method of claim 13, further comprising recessing the device isolation pattern of the cell region and exposing upper surfaces and sidewalls of the first conductive layers, after the removing of the first and second buffer layers.

16. The method of claim 15, further comprising:
forming a third insulating layer on the semiconductor substrate to be conformal with the exposed upper surfaces and sidewalls of the first conductive layers;
removing the third insulating layer of the peripheral region and exposing an upper surface of the second conductive pattern of the peripheral region; and
forming a third conductive layer on the exposed upper surface of the second conductive pattern and the third insulating layer of the cell region.

17. The method of claim 16, further comprising a fourth conductive layer on the third conductive layer.

18. The method of claim 17, wherein the fourth conductive layer includes at least one of a tungsten layer and a tungsten silicide layer.

19. The method of claim 15, further comprising:
forming a third insulating layer on the semiconductor substrate to be conformal with the exposed upper surfaces and sidewalls of the first conductive layers;
forming a third conductive layer on the third insulating layer;
removing the third conductive layer and the third insulating layer of the peripheral region, and exposing the second conductive pattern of the peripheral region; and
forming a fourth conductive layer on the exposed second conductive pattern of the peripheral region.

20. The method of claim 19, wherein the fourth conductive layer comprises at least one of a tungsten layer and a tungsten silicide layer.
